(19) United States
(12) Patent Application Publication
(10) Pub. No.: US 2010/0219521 A1
(43) Pub. Date: Sep. 2, 2010

(54) WINDOW TYPE SEMICONDUCTOR PACKAGE

(76) Inventors: Kuo-Yuan LEE, Kaohsiung (TW); Yung-Hsiang Chen, Kaohsiung (TW); Wen-Chun Chiu, Kaohsiung (TW)

Correspondence Address: Muncy, Geissler, Olds & Lowe, PLLC, 4000 Legato Road, Suite 310, FAIRFAX, VA, 22033, US

(21) Appl. No.: 12/437,837

(22) Filed: May 8, 2009

(30) Foreign Application Priority Data
Feb. 27, 2009 (TW) 098106548

(51) Int. Cl. H01L 23/04

(52) U.S. Cl. 257/680; 257/E23.18; 257/690

(57) ABSTRACT

A window-type semiconductor package is revealed, primarily comprising a substrate with an interconnection channel, a chip on the substrate, a die-attach adhesive between the chip and the substrate, and an encapsulant filling the interconnection channel. A first solder mask formed on the top surface of the substrate has a specific pattern. The die-attach adhesive bonds the active surface of the chip to the first solder mask with the bonding pads of the chip aligned inside the interconnection channel. The first solder mask has an opening to expose the interconnection channel and further to form an indentation from the interconnection channel to expose the top surface to prevent damaging of the active surface of the chip adjacent to the edges of the interconnection channel to ensure the integrity and yield of the final products.

### FIELD OF THE INVENTION

The present invention relates to semiconductor devices, and more particularly to window-type semiconductor packages.

### BACKGROUND OF THE INVENTION

In semiconductor packages, window-type semiconductor packages are capable of designing the internal interconnections only on the interconnection channels such as through holes, slots, or penetrating windows according to different package structures and shapes, to effectively shrink the package dimensions to meet the developing trend of electronic products for thin, light, small, and short. The interconnection channels allow metal wires or other wire-type conductive components to pass through the substrate to electrically connect the substrate to the chip so that the metal wires can be effectively hidden and the package profiles can be effectively reduced. After electrical connections, an encapsulant encapsulates the metal wires and the chips for protection. However, interfaces between the encapsulant and the die-attach adhesive are located at the edges of the interconnection channel, therefore, the active surface of the chip is covered by the encapsulant as well as the die-attach adhesive. Moreover, since the ICs are formed on the active surface of the chip, ICs can easily be damaged by the encapsulant and/or the die-attach adhesive.

As shown in FIG. 1, a conventional window-type semiconductor package 100 primarily comprises a substrate 110, a chip 120, a die-attach adhesive 130, a plurality of metal wires 140, and an encapsulant 150 where the substrate 110 has a top surface 111, a bottom surface 112, and an interconnection channel 113. Normally, the substrate 110 such as a printed circuit board has patterned circuitry and solder masks. An internal solder mask 114 and an external solder mask 115 are formed on the top surface 111 and the bottom surface 112 respectively. A plurality of ball pads 117 exposed from the external solder mask 115 are disposed on the bottom surface 112 of the substrate 110.

The top surface 111 of the substrate 110 is to carry the chip 120 by using the die-attach adhesive 130 to attach the active surface 121 of the chip 120 to the substrate 110. The die-attach adhesive 130 is disposed on the internal solder mask 114 on the top surface 111 of the substrate 110 without covering the interconnection channel 113 to attach the active surface 121 of the chip 120 to the internal solder mask 114. A plurality of bonding pads 122 of the chip 120 are electrically connected to the substrate 110 by the metal wires 140 passing through the interconnection channel 113. The encapsulant 150 encapsulates the chip 120 and the bonding pads 122. Furthermore, a plurality of solder balls 160 are disposed on the ball pads 117 as external electrical terminals.

As shown in FIG. 1, during molding processes, the encapsulant 150 is formed in the interconnection channel 113 to fill the interconnection channel 113 and also the gap between the active surface 121 of the chip 120 and the internal solder mask 114 on the substrate 110 so that the die-attach adhesive 130 is encapsulated. Since the height of the gap (equal to the thickness of the die-attach adhesive 130) is much smaller than the width of the interconnection channel 113, the encapsulant 150 can not easily fill into the gap leading voids on the active surface 121 of the chip 120. Moreover, the impact of mold flow during molding processes and the stresses after molding will damage the active surface 121 of the chip 120 leading to reliability issues of the semiconductor package 100.

As shown in FIG. 2, another conventional window-type semiconductor package 200 is about the same as the semiconductor package 100 as shown in FIG. 1 but without the internal solder mask to eliminate the cost of the internal solder mask and to enhance the die bonding strength and the adhesion between the substrate 110 and the encapsulant 150. However, in this package structure, even though there is no internal solder mask disposed on the top surface 111 of the substrate 110, the gap formed adjacent to the interconnection channel 113 and between the chip 120 and the substrate 110 is too small to be completely filled and is easily affected by the die-attaching pressure and by the viscosity property of the die-attach adhesive 130. Voids may be hidden in the gap in contact with the active surface 121. The damages to the active surface 121 of the chip 120 remain unsolved. Furthermore, since the external solder mask 115 is disposed on the bottom surface 111 of the substrate 110, the substrate 110 easily experiences warpage due to different thermal stresses exerted on the top and bottom surfaces under temperature cycling conditions where the stresses caused by warpage may break the chip 120 or damage the electrical components.

### SUMMARY OF THE INVENTION

The main purpose of the present invention is to provide a window-type semiconductor package to prevent damages to the active surface of a chip adjacent to the interconnection channel to ensure the integrity and yield of the final products.

The second purpose of the present invention is to provide a window-type semiconductor package to prevent a patternized solder mask on the top surface of the substrate from breaks or delamination by partially routing the substrate during the formation of the interconnection channel.

The third purpose of the present invention is to provide a window-type semiconductor package to effectively control the bleeding of the die-attach adhesive to avoid bleeding to the bonding pads of a chip to ensure the quality of die-attaching processes.

According to the present invention, a window-type semiconductor package is revealed, primarily comprising a substrate, a chip, a die-attach adhesive, a plurality of metal wires, and an encapsulant. The substrate has a top surface, a bottom surface, and at least an interconnection channel where a first solder mask is disposed on the top surface. The chip has an active surface and a plurality of bonding pads formed on the active surface. The die-attach adhesive bonds the active surface of the chip to the first solder mask of the substrate with the bonding pads aligned in the interconnection channel. The metal wires pass through the interconnection channel and electrically connect the bonding pads of the chip to the substrate. The encapsulant is at least formed inside the interconnection channel to encapsulate the metal wires. Furthermore, the first solder mask has a first opening exposing the interconnection channel and further forming an indentation from the interconnection channel to expose the top surface for easily filling of the encapsulant where the thickness of the encapsulant filling in the indentation is greater than the one of the die-attach adhesive.

The window-type semiconductor package according to the present invention has the following advantages and functions:
1. Through the specific incomplete coverage of the first solder mask on the top surface of the substrate as a technical means, the opening of the first solder mask has an indentation formed from the interconnection channel for easily filling the encapsulant where the thickness of the encapsulant in the indentation is greater than the one of the die-attach adhesive to prevent damages of the active surface of the chip at the edges of the interconnection channel to ensure the integrity and yield of the final products, moreover, to completely fill the indentation by the encapsulant without any voids.
2. Through the specific incomplete coverage of both solder masks disposed on the top and bottom surfaces of the substrate as a technical means, the routing traces of the interconnections of the substrates will not be covered by the top and bottom solder masks during the formation of the interconnection channel by partially routing of the substrate to prevent or reduce the breaks or delamination of the solder mask disposed on the top surface of the substrate.
3. Through the specific incomplete coverage of the first solder mask disposed on the top surface of the substrate as a technical means, the opening of the first solder mask has an indentation formed from the interconnection channel for easily filling the encapsulant and also to provide a bleeding reservoir to effectively control the bleeding of the die-attach adhesive and to enhance the bleeding control to the bonding pads of a chip to ensure the quality of die-attaching processes.

### DESCRIPTION OF THE DRAWINGS

FIG. 1 is a cross-sectional view of a conventional window-type semiconductor package.

FIG. 2 is a cross-sectional view of another conventional window-type semiconductor package.

FIG. 3 is a cross-sectional view of a window-type semiconductor package with a partially enlarged view at the indentation of the first solder mask according to the first embodiment of the present invention.

FIGS. 4A to 4D are the top views of a window-type semiconductor package showing several practicable dimensions of the indentations formed by the first solder mask according to the first embodiment of the present invention.

FIGS. 5A and 5B are the cross-sectional views of a substrate of a window-type semiconductor package during the formation of interconnection channel by partially routing according to the first embodiment of the present invention.

FIG. 6 is a cross-sectional view of another window-type semiconductor package according to the second embodiment of the present invention.

FIG. 7 is a cross-sectional view of another window-type semiconductor package according to the third embodiment of the present invention.

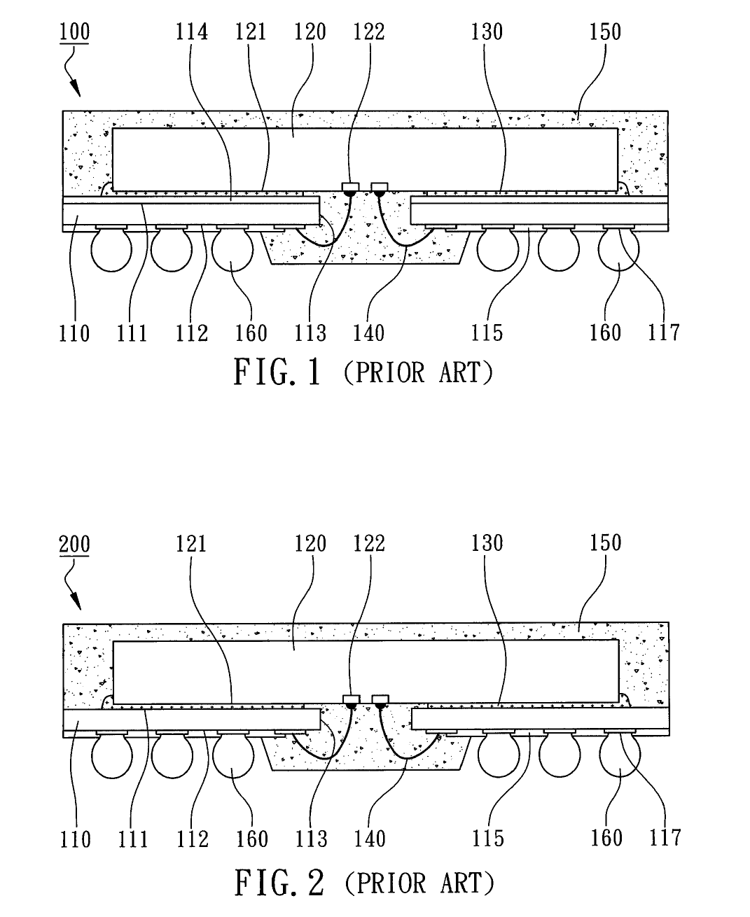

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

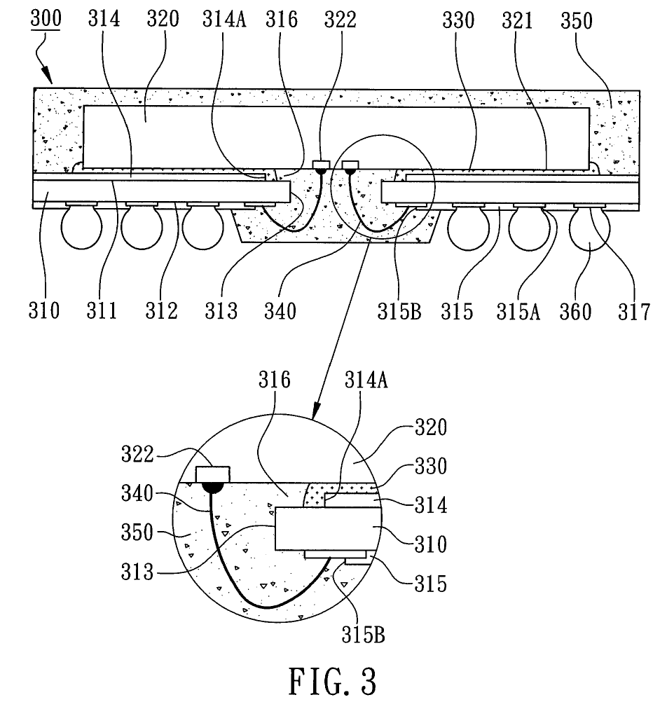

According to the preferred embodiment of the present invention, a window-type semiconductor package is illustrated in FIG. 3 for a cross-sectional view with a partially enlarged view at the indentation of the first solder mask. The window-type semiconductor package 300 primarily comprises a substrate 310, a chip 320, a die-attach adhesive 330, a plurality of metal wires 340, and an encapsulant 350.

The substrate 310 is a circuit board with single-layer or multiple-layer circuitry such as printed circuit board, ceramic substrate, glass substrate, thin film substrate, or pre-mold leadframe. Preferably, the substrate 310 can be a substrate with single-layer circuitry with lower costs to eliminate the complicated circuit design and manufacture processes to enhance high-speed signal processing and to reduce the manufacturing cost with appropriate carrier strengths. Alternatively, the substrate 310 has multiple circuitries, a plurality of electrical plated through holes are disposed in the substrate 310, not shown in the figures, to electrically connect different layers of circuitries.

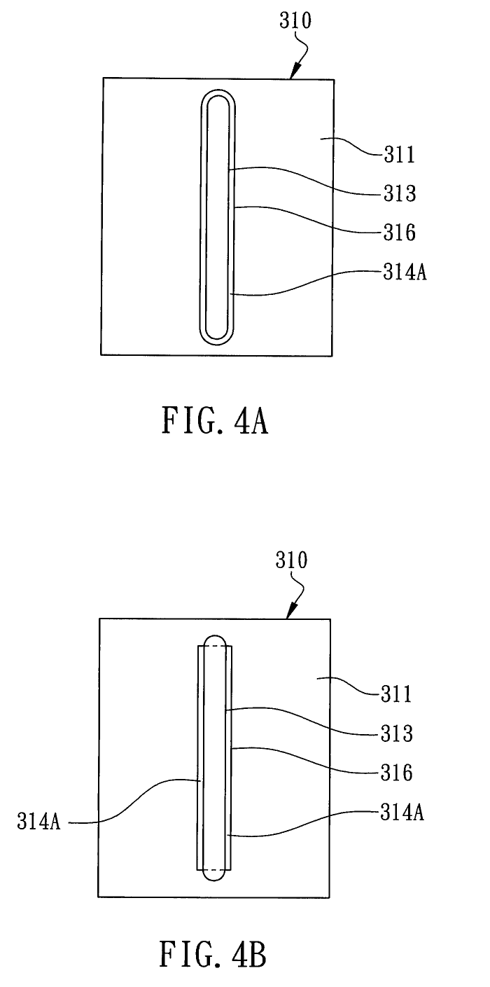

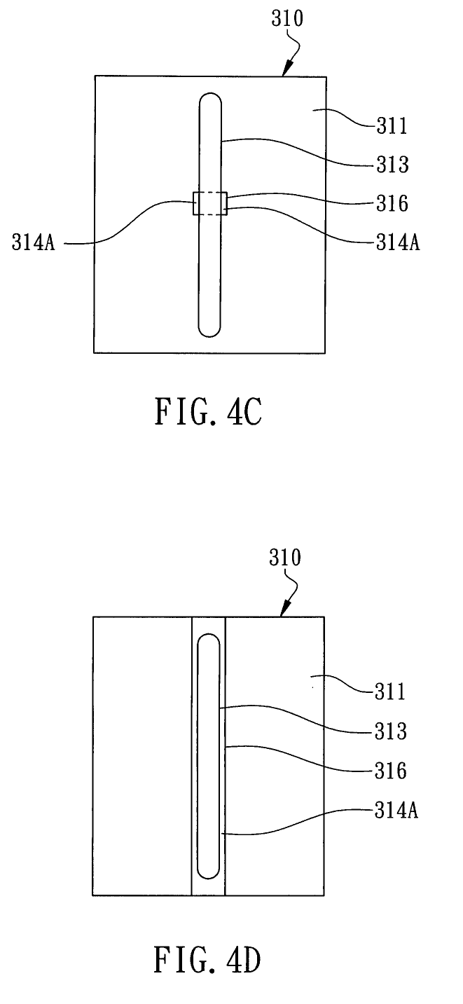

The substrate 310 has a top surface 311, a bottom surface 312, and at least an interconnection channel 313 where a first solder mask 314 is formed on the top surface 311. In the present embodiment, as shown in FIG. 3, a second solder mask 315 is formed on the bottom surface 312. The first solder mask 314 and the second solder mask 315 are so called solder resist disposed by printing on the substrate surfaces in liquid form to form a surface protection layer to protect the circuitry from moisture, contaminations, and others. Normally the first solder mask 314 and the second solder mask 315 can be liquid photoimagable solder mask (LPI), photoimagable cover layer (PIC), or non-photosensitive dielectric layer or cover layer. As shown in FIG. 3 and FIG. 4A, the interconnection channel 313 is a central slot penetrating through the top surface 311 and the bottom surface 312. In the present embodiment, a circuitry is formed on the bottom surface 312 of the substrate 310 to form a plurality of ball pads 317 and a plurality of internal pads for electrical connections.

As shown in FIG. 3, the chip 320 is faced-down disposed on the top surface 311 of the substrate 310 where the chip 320 has an active surface 321 and a plurality of bonding pads 322 disposed on the active surface 321. The chip 320 can be a microprocessor, a graphic chip, or all kinds of memory chips. In the present embodiment, the bonding pads 322 are disposed at the center of the active surface 321 of the chip 320, i.e., central pads.

The die-attach adhesive 330 is disposed on the first solder mask 314 and bonds the active surface 321 of the chip 320 to the first solder mask 314 of the substrate 310 with the bonding pads 322 aligned in the interconnection channel 313. In detail, the die-attach adhesive 330 is partially disposed on the first solder mask 314 where the die-attach adhesive 330 can be chosen from B-stageable adhesive, adhesive film/tape, epoxy paste, non-conductive paste, liquid paste, or other die-attach adhesive with multiple-curing stages.

The metal wires 340 pass through the interconnection channel 313 and electrically connect the bonding pads 322 of the chip 320 to the substrate 310 such as electrically connecting to the bonding fingers on the bottom surface 312 of the substrate 310 adjacent the interconnection channel 313. In the present embodiment, the metal wires 340 are bonding wires formed by wire bonding. The encapsulant 350 is at least formed inside the interconnection channel 313 to encapsulate the metal wires 340. The encapsulant 350 is an electrically isolating component which can be formed by transfer molding such as epoxy molding compounds (EMC). In detail, the encapsulant 350 is further formed on the top surface 311 of the substrate 310 to completely encapsulate the chip 320 and the die-attach adhesive 330 to protect and isolate from moisture and contaminations from the environment.

In detail, as shown in FIG. 3 with the partially enlarged view, the first solder mask 314 has a first opening 316 exposing the interconnection channel 313 completely and further forming an indentation 314A from the interconnection channel 313 to expose the first solder mask 314 for easily filling the encapsulant 350. Moreover, the thickness of the encapsulant 350 filling in the indentation 314A is greater than the one of the die-attach adhesive 330. Therein, the thickness of the encapsulant 350 filling in the indentation 314A is equal to the vertical distance from the active surface 321 to the exposed top surface 311 from the indentation 314A. The thickness of the die-attach adhesive 330 is equal to the vertical distance from the active surface 321 to the first solder mask 314. Therefore, the indentation 314A can effectively increase the gap between and the chip 320 and the substrate 310 adjacent to the edges of the interconnection channel 313 so that the thickness of the encapsulant 350 in the indentation 314A is equal to the thickness of the die-attach adhesive 330 plus the thickness of the first solder mask 314. Compared to the conventional window-type semiconductor package, the gap for encapsulation is greatly increased. Even the thickness of the die-attach adhesive 330 can not accurately be controlled during die-attaching processes, the indentation 314A can provide the minimum spacing to enhance the filling capability of the encapsulant 350 in the indentation 314A and prevent the damages of the active surface 321 of the chip 320 adjacent the interconnection channel 313 to ensure the integrity and yield of the final products.

To be more specific, as shown from FIG. 4A to FIG. 4C, the shape of the indentation 314A of the first solder mask 314 can be circular, rectangular, or other shape. As shown in FIG. 4A, the indentation 314A is annular to encircle the interconnection channel 313 so that the first opening 316 of the first solder mask 314 is not completely aligned with the interconnection channel 313. Or, as shown in FIG. 4B, the indentation 314A is shaped like two parallel strips disposed on both sides of the interconnection channel 313 to avoid direct contacts of the first solder mask 314 to the two corresponding parallel sides of the interconnection channel 313 during routing the interconnection channel 313. Or in one of the embodiments, as shown in FIG. 4C, the indentation 314A is shaped like a plurality of blocks disposed at the center on two corresponding sides of the interconnection channel 313 so that the first solder mask 314 will not direct contact with the central or sensitive sections of two corresponding parallel sides of the interconnection channel 313 where bubbles are easily formed. Or, in another embodiment, as shown in FIG. 4D, the indentation 314A can be a slot connecting through two corresponding sides of the top surface 311 of the substrate 310 to enhance the mold flow from one end of the interconnection channel 313 to the other end to achieve completely filling of encapsulant 350 in the interconnection channel 313. The shape of the indentation 314A can be controlled by photo-processing the first solder mask 314. Or, the indentation 314A can be formed at the same time as forming the first solder mask 314 by screen printing without extra manufacturing processes nor costs.

Furthermore, the indentation 314A can serve as a bleeding reservoir to effectively control the bleeding of the die-attach adhesive 330. When bleeding, the bleeding of the die-attach adhesive 330 can flow into the indentation 314A of the first solder mask 314 as shown in the enlarged view in FIG. 3. However, not completely filling the indentation 314A is preferred so that the bleeding of the die-attach adhesive 330 will not contaminate the bonding pads 322 to ensure the quality of die-attaching processes.

As shown in FIG. 3 again, the second solder mask 315 has a plurality of second openings 315A exposing the ball pads 317 on the bottom surface 312. A plurality of solder balls 360 are placed on the ball pads 317 of the substrate 310 through the second openings 315A as external electrical terminals to make the window-type semiconductor package 300 as a BGA package. To be more specific, the second solder mask 315 further has an exposed area 315B indented from the interconnection channel 313 to expose the bottom surface 312 and the bonding fingers on the bottom surface 312 for wire-bonding purposes. Therefore, the solder masks 314 and 315 of the substrate 310 do not completely cover the top and bottom surfaces 311 and 312 of the substrate 310 without direct contacts with the interconnection channel 313 to improve manufacture yields during the formation of interconnection channel 313 through partially routing.

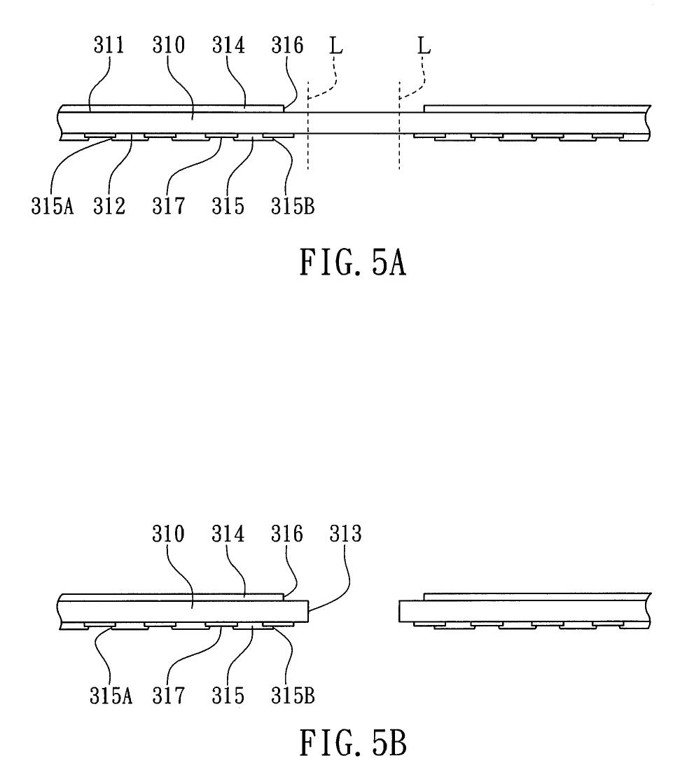

As shown in FIG. 5A and FIG. 5B, the formation of interconnection channel 313 through partially routing on the substrate 310 is further illustrated to manifest the effectiveness of the present invention.

As shown in FIG. 5A, the first solder mask 314 and the second solder mask 315 are disposed on the top surface 311 and the bottom surface 312 of the substrate 310 respectively. The disposition of the first solder mask 314 and the second solder mask 315 can be classified as follows, screen printing, curtain printing, spray printing, roller printing, etc. The thickness of the first solder mask 314 is the same as the one of the second solder mask 315 but in different embodiment the thickness of the first solder mask 314 can be appropriately increased more than the one of the second solder mask 315 to enhance filling of the encapsulant 350 and to control bleeding of the die-attach adhesive 330.

As shown in FIG. 5A and FIG. 5B, the first opening 316 of the first solder mask 314 exposes the routing line L of the interconnection channel 313 of the substrate 310 where the first solder mask 314 does not cover the routing line L nor direct contact with the interconnection channel 313. The exposed area 315B of the second solder mask 315 also exposes the interconnection channel 313 and the internal bonding pads without covering the routing line L where the exposed area 315B of the second solder mask 315 does not directly contact with the interconnection channel 313 after routing.

As shown in FIG. 5A and FIG. 5B, the routing blade (not shown in the figures) cutting off the substrate 310 along the routing line L will not direct contact with neither the first solder mask 314 nor the second solder mask 315 during the formation of the interconnection channel 313.

Therefore, in the above mentioned window-type semiconductor package 300, the indentation 314A formed by the first solder mask 314 is capable of the encapsulant 350 filling in the indentation 314A during molding processes and to enlarge the space of the indentation 314A and to prevent damages to the active surface 321 of the chip 320 to ensure integrity and yield of the final products. Furthermore, the first solder mask 314 and the second solder mask 315 of the substrate 310 do not be broken or delaminated during the formation of the interconnection channel 313 on the substrate 310 by partially routing.

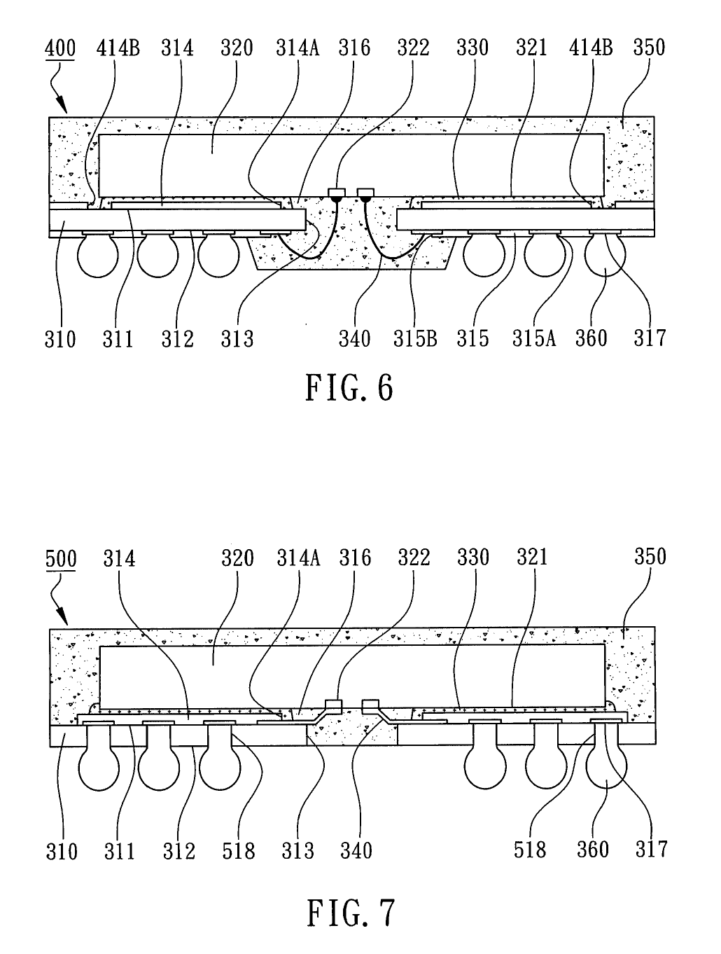

According to the second embodiment of the present invention, another window-type semiconductor package is illustrated in a cross-sectional view of FIG. 6. The window-type semiconductor package 400 primarily comprises a substrate 310, a chip 320, a die-attach adhesive 330, a plurality of metal wires 340, and an encapsulant 350 where the major components of the second embodiment is the same as the ones in the first embodiment with the same functions. Therefore, the detail will not be described again.

Preferably, the first solder mask 314 of the substrate 310 has a plurality of peripheral openings 414B aligned to a plurality of corners of the chip 320 to avoid stress concentration and adhesive bleeding. Further preferably, the peripheral opening 414B are connected with the first opening 316 to form as a loop to encircle from the edges of the chip 320 to the centers of the bonding pads 322 to make the first solder mask 314 under the chip 320 become at least two island-like supporting pads to serve as the deposition area for the die-attach adhesive 330 and to provide molding gap after die-attaching processes where the thickness of the first solder mask 314 plus the thickness of the die-attach adhesive 330 can act as the molding gap between the chip 320 and the substrate 310. Therefore, the indentation 314A and the peripheral opening 414B can provide bleeding reservoir for the die-attach adhesive 330 to effectively control the bleeding of the die-attach adhesive 330. When bleeding, the die-attach adhesive 330 will be conducted into the indentation 314A and the peripheral opening 414B of the first solder mask 314 so that the die-attach adhesive 330 will not bleed to contaminate the bonding pads 322 nor the top surface 311 of the substrate 310 to ensure the quality of die-attaching processes.

According to the third embodiment of the present invention, another window-type semiconductor package is illustrated in a cross-sectional view of FIG. 7 where the major components of the second embodiment is the same as the ones in the first embodiment with the same functions. Therefore, the detail will not be described again. The window-type semiconductor package 500 primarily comprises a substrate 310, a ship 320, a die-attach adhesive 330, a plurality of metal wires 340, and an encapsulant 350.

In the present embodiment, the substrate 310 is a substrate with single-layer circuitry to reduce manufacture cost and to eliminate the complicated routing design and processes. As shown in FIG. 7, the metal wires 340 can be internal components of the substrate 310 such as suspended inner leads. The circuitry disposed on the top surface 311 of the substrate 310 includes the ball pads 317 and the metal wires 340 so that ILB bonding head can bond the metal wires 340 to the bonding pads 322 to electrically connect to the chip 320. The substrate 310 further has a plurality of through holes 518 to expose the ball pads 317 on the top surface 311 of the substrate 310. The solder balls 360 are bonded to the ball pads 317 through the through holes 518 as external electrodes. The first solder mask 314 only covers the ball pads 317 without fully covering the top surface 311 of the substrate 310. The second solder mask on the bottom surface 311 of the substrate 310 can be eliminated. To be more specific, except having the first opening 316, the peripheries of the first solder mask 314 do not direct contact with the top surface 311 of the substrate 310 to form independent and electric isolated supporting pads disposed in one step and to provide an indentation 314A from the interconnection channel 313 for filling the encapsulant 350.

During die-attaching processes, the indentation 314A can serve as a bleeding reservoir to effectively control the bleeding of the die-attach adhesive 330 and to enhance the filling of the encapsulant 350 to the indentation 314A.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A window-type semiconductor package comprising:
a substrate having a top surface, a bottom surface, at least an interconnection channel and a first solder mask formed on the top surface;
a chip having an active surface and a plurality of bonding pads disposed on the active surface;
a die-attach adhesive bonding the active surface of the chip to the first solder mask to align the bonding pads inside the interconnection channel;
a plurality of metal wires passing through the interconnection channel to electrically connect the bonding pads to the substrate; and
an encapsulant at least formed inside the interconnection channel to encapsulate the metal wires;
wherein the first solder mask has a first opening exposing the interconnection channel and further forming an indentation from the interconnection channel to expose the top surface so that the thickness of the encapsulant filling in the indentation is greater than the one of the die-attach adhesive.

2. The window-type semiconductor package as claimed in claim 1, wherein the indentation is annular to encircle the interconnection channel.

3. The window-type semiconductor package as claimed in claim 1, wherein the indentation is shaped like two parallel strips disposed on both sides of the interconnection channel.

4. The window-type semiconductor package as claimed in claim 1, wherein the indentation is shaped like a plurality of blocks disposed at the center on two corresponding sides of the interconnection channel.

5. The window-type semiconductor package as claimed in claim 1, wherein the indentation is a slot connecting through the two corresponding sides of the top surface of the substrate.

6. The window-type semiconductor package as claimed in claim 1, wherein the encapsulant further disposes on the top surface of the substrate.

7. The window-type semiconductor package as claimed in claim 6, wherein the encapsulant completely encapsulates the chip and the die-attach adhesive.

8. The window-type semiconductor package as claimed in claim 1, wherein the bonding pads includes a plurality of central pads.

9. The window-type semiconductor package as claimed in claim 1, wherein the substrate is a circuit substrate.

10. The window-type semiconductor package as claimed in claim 1, wherein the substrate further has a second solder mask formed on the bottom surface and having an exposed area indented from the interconnection channel to expose the bottom surface.

11. The window-type semiconductor package as claimed in claim 10, wherein the second solder mask has a plurality of second opening exposing a plurality of ball pads on the bottom surface, and further comprising a plurality of solder balls bonded to the ball pads through the second openings.

12. The window-type semiconductor package as claimed in claim 1, wherein the substrate further has a plurality of through holes exposing a plurality of ball pads on the top surface, and further comprising a plurality of solder balls bonded to the ball pads through the through holes.

13. The window-type semiconductor package as claimed in claim 12, wherein the first solder mask only covers the ball pads without fully covering the top surface of the substrate.

14. The window-type semiconductor package as claimed in claim 1, wherein the substrate is a substrate with single-layer circuitry.

15. The window-type semiconductor package as claimed in claim 1, wherein the first solder mask has a plurality of peripheral openings aligned to a plurality of corners of the chip.

16. The window-type semiconductor package as claimed in claim 15, wherein the peripheral openings are connected with the first opening to form as a loop.
